(19) United States
(12) Patent Application Publication
(10) Pub. No.: US 2010/0193018 A1
(43) Pub. Date: Aug. 5, 2010

(54) ROBUST PHOTOVOLTAIC CELL

(75) Inventors: Rebekah Kristine-Ligman Feist, Midland, MI (US); Buford I. Lemon, Midland, MI (US)

Correspondence Address: The Dow Chemical Company, P.O. BOX 1967, Midland, MI, 48641, US

(73) Assignee: Dow Global Technologies Inc., Midland, MI (US)

(21) Appl. No.: 12/697,365

(22) Filed: Feb. 1, 2010

Related U.S. Application Data
(60) Provisional application No. 61/149,123, filed on Feb. 2, 2009.

(51) Int. Cl. H01L 31/032; H01L 31/00

(52) U.S. Cl. 136/255; 438/94; 438/95; 257/E31.026

(57) ABSTRACT

This disclosure describes devices and methods in which photovoltaic cells are configured such that an active layer of a photovoltaic cell is protected against an environmental condition by another active cell layer that is more robust against the environmental condition. In one aspect, the disclosure describes a multi-junction photovoltaic device that includes (a) an upper photovoltaic cell portion that has a first plurality of active layers of films, at least a subset of which form an upper photovoltaic sub-cell and (b) a lower photovoltaic cell portion disposed below the upper photovoltaic cell portion that has a second plurality of layers of films, at least a subset of which form a lower photovoltaic sub-cell. The first plurality of active layers, of the upper cell portion, include at least two layers of films having different degrees of robustness from each other against environmental conditions, such as exposure to water or oxygen. The two active layers are disposed such that the layer having the lower degree of robustness is located below the other layer having the higher degree of robustness. Specific examples of materials and method used to make multi-junction photovoltaic cells are also described.

### CROSS-REFERENCE TO RELATED APPLICATIONS

This application claims the benefit of U.S. Provisional Application Ser. No. 61/149,123, filed Feb. 2, 2009; which application is incorporated herein by reference.

### BACKGROUND

Non-polluting sources of energy are actively being sought as a replacement for the burning of fossil fuels. The generation of energy from solar radiation is one type of clean energy that is receiving significant attention. Solar energy collectors, such as photovoltaic cells (also referred to as “solar cells”), may be used to generate energy where and when there is adequate sunlight.

Since photovoltaic articles are frequently located outdoors, considerable efforts have been devoted to designing photovoltaic cells that are sufficiently robust against environmental conditions while achieving high efficiencies.

### SUMMARY

This disclosure describes devices and methods in which photovoltaic cells are configured such that an active layer of a photovoltaic cell is protected against one or more environmental conditions by another active cell layer that is more robust against such an environmental condition such as oxygen or water.

In one aspect, the disclosure describes a multi-junction photovoltaic device that includes (a) an upper photovoltaic cell portion that has a first plurality of active layers of films, at least a subset of which form an upper photovoltaic sub-cell and (b) a lower photovoltaic cell portion disposed below the upper photovoltaic cell portion that has a second plurality of layers of films, at least a subset of which form a lower photovoltaic sub-cell. The upper photovoltaic cell portion and the lower photovoltaic cell portion either can be prepared by adding layer upon layer or can be separately prepared and then stacked on each other. The upper and lower photovoltaic cells can be connected to each other by a transition layer comprising a transparent conducting oxide. The upper cell portion is adapted to absorb a first spectral portion of a photon radiation and to transmit a second spectral portion of the photon radiation; the lower cell portion is adapted to receive the photon radiation passing through the upper photovoltaic cell portion. The first

plurality of active layers, of the upper cell portion, include at least two layers of films having different degrees of robustness from each other against environmental conditions, such as exposure to water or oxygen. The two active layers are disposed such that the layer having the lower degree of robustness is located below the other layer having the higher degree of robustness. The layer having the higher degree of robustness can be the uppermost layer of the multi-junction photovoltaic device and thus be exposed to the environment in operation. With this arrangement, the upper layer serves both as an active layer in the upper cell portion and as a protective layer for the less robust layer against environmental conditions, thereby reducing the need for and/or requirements of any extra, passive protective layer, which protective layer increases the complexity of the device and may reduce the efficiency of the photovoltaic device and/or increase the cost of the device.

As used in this specification, a layer or material is “active” if it participates electrically in a photovoltaic device. Examples of active layers include buffer layers, absorber layers, tunnel junction layers and transparent electrical contact layers. Examples of non-active, or passive, layers include glass or polymeric encapsulating layers disposed on top of solar cells to shield the internal structures of the solar cells from the environment but not otherwise contributing electrically to the operations of the solar cells.

In another aspect of the present disclosure, at least one of the first plurality of active layers of films comprises a layer of IB-IIIA-chalcogenide, such as IB-IIIA-selenides, IB-IIIA-sulfides, or IB-IIIA-selenide sulfides. More specific examples include copper indium selenides, copper indium gallium selenides, copper gallium selenides, copper indium sulfides, copper indium gallium sulfides, copper gallium selenides, copper indium sulfide selenides, copper gallium sulfide selenides, and copper indium gallium sulfide selenides (all of which are referred to herein as CIGSS). These can also be represented by the formula CuIn(1−x)GaxSe(2−y)Sy where x is 0 to 1 and y is 0 to 2. The copper indium selenides and copper indium gallium selenides are preferred.

In another aspect, the layer having the higher degree of robustness of the two layers comprises a first transparent conducting oxide layer, such as oxides of tin, indium and combinations thereof. This includes such materials as tin oxide, indium oxide, tin-doped indium oxide, fluorine-doped tin oxide, titanium oxide, zirconium oxide or a combination thereof.

In another aspect, the layer having the lower degree of robustness comprises a layer of a sulfide or an oxide of a metal selected from a group consisting of cadmium, zinc, indium or combinations thereof. This layer may be a multi-layer structure itself. For example, the layer having the lower degree of robustness can comprise a layer comprising cadmium and sulfur and an adjacent layer comprising zinc and oxygen. These layers often form the buffer layers in the photovoltaic cell.

In another aspect of the present disclosure, the layer having the higher degree of robustness comprises two layers of films, both having higher degrees of robustness than the layer having the lower degree of robustness.

In another aspect, at least one of the second plurality of layers of films comprises a layer of IB-IIIA-chalcogenide.

In another aspect of the disclosure, the upper and lower photovoltaic sub-cells have opposite polarities from each other, i.e., the cathodes (such as CdS layers) of the two sub-cells are disposed between the anodes (such as IB-IIIA-chalcogenide layers) of the sub-cells, or vice versa.

In another aspect, a multi-junction photovoltaic device includes (a) an upper photovoltaic cell portion comprising a first plurality of active layers of films, at least a subset of which form an upper heterojunction photovoltaic sub-cell comprising a first absorber layer and a first buffer layer, and (b) a lower photovoltaic cell portion comprising a second plurality of active layers of films, at least a subset of which form a lower heterojunction photovoltaic sub-cell comprising a second absorber layer and a second buffer layer. The upper cell portion is adapted to absorb a first spectral portion of photon radiation and to transmit a second spectral portion of the photon radiation, and the lower cell portion is disposed below the upper photovoltaic cell portion and adapted to receive the photon radiation passing through the upper photovoltaic cell portion. The buffer layers are disposed between the absorber layers. Each of the absorber layers can comprise a IB-IIIA-chalcogenide, and each of the buffer layers can comprise a layer of a sulfide or oxide of a metal selected from a group consisting of cadmium, zinc and combinations thereof.

In another aspect of the present disclosure, any device described above can be flexible.

A method of making a multi-junction photovoltaic device is also disclosed. In one aspect, the method includes (a) determining an environmental condition, such as moisture and oxygen level, under which the device is to operate and (b) forming an upper photovoltaic cell portion comprising a first plurality of active layers of films, at least a subset of which form an upper photovoltaic sub-cell, the first plurality of layers comprising at least two layers of films having different degrees of robustness from each other against the environmental condition. The forming step comprises: (i) disposing the two layers such that the layer having the higher degree of robustness is above the layer having the lower degree of robustness, and (ii) forming a lower photovoltaic cell portion below the upper photovoltaic cell portion, thereby enabling the lower photovoltaic cell portion to receive photon radiation passing through the upper photovoltaic cell portion, the lower photovoltaic cell portion comprising a second plurality of layers of films at least a subset of which form a lower photovoltaic sub-cell. The multi-junction photovoltaic device can be made by joining the upper and lower cell portions after both portions have been formed. Alternatively, the multi-junction photovoltaic device can be made by sequentially forming each layer on top of those already formed. An additional transition layer comprising a transparent conductive oxide layer between the upper and lower photovoltaic sub-cells can also be formed.

In another aspect, forming the upper photovoltaic cell portion can comprise depositing a transparent conductive oxide film, a IB-IIIA-chalcogenide film and a CdS film either in order, or in reverse order, so that the transparent conductive oxide film is the uppermost of the three layers in the multi-junction photovoltaic device. Additionally, forming the lower photovoltaic cell portion can comprise depositing a IB-IIIA-chalcogenide film and a CdS film.

These and various other features as well as advantages will be apparent from a reading of the following detailed description and a review of the associated drawings. Additional features are set forth in the description that follows and, in part, will be apparent from the description, or may be learned by practice of the described embodiments. The benefits and features will be realized and attained by the structure particularly pointed out in the written description and claims hereof as well as the appended drawings.

It is to be understood that both the foregoing general description and the following detailed description are exemplary and explanatory and are intended to provide further explanation of the invention as claimed.

### BRIEF DESCRIPTION OF THE DRAWINGS

The following drawing figures are illustrative of embodiments of systems and methods described below and are not meant to limit the scope of the disclosure in any manner, which scope shall be based on the claims appended hereto.

FIG. 1 schematically illustrates a multi-junction photovoltaic device according to one aspect of the present disclosure.

FIG. 2 schematically illustrates a multi-junction photovoltaic device according to another aspect of the present disclosure.

FIG. 3 illustrates a method of making a multi-junction photovoltaic device according to another aspect of the disclosure.

FIG. 4 illustrates making a multi-junction photovoltaic device by mechanically stacking two cell portions according to another aspect of the disclosure.

### DETAILED DESCRIPTION OF ILLUSTRATIVE EMBODIMENTS

This disclosure describes devices and methods in which photovoltaic cells are configured such that an active layer of a photovoltaic cell is protected against an environmental condition by another active cell layer that is more robust against certain environmental conditions, such as exposure to moisture and oxygen. One of the advantages of certain embodiments is that the need for using additional, passive layers to prevent moisture and/or oxygen (or other problematic environmental elements) ingress into the multi-junction photovoltaic cells is reduced or eliminated because the cell is fabricated in such a way as to be protected by relatively robust active layers located exterior relative to the less robust layers.

The following description of various embodiments is merely exemplary in nature and is in no way intended to limit the disclosure. While various embodiments have been described for purposes of this specification, various changes and modifications may be made which will readily suggest themselves to those skilled in the art, and which are encompassed in the disclosure.

Photovoltaic (“PV”) cells are solar energy collectors that convert solar radiation (sunlight) into electricity. Various types of photovoltaic cells are known. For example, thin-film, polycrystalline, heterojunction photovoltaic (solar) cells are known. Another example of PV cells is a chalcogenide-based thin-film PV cell. One particularly useful type of chalcogenide-based thin-film PV cell employs a selenized copper compound such as copper indium selenides (“CIS”), or gallium-substituted copper indium selenides (“CIGS”) as the absorber material. In one type of PV cells, for example, the cell has the following layers in order molybdenum (Mo), a CIGSS layer, cadmium sulfide (CdS), preferably an intrinsic Zinc oxide layer (iZnO), and aluminum-doped zinc oxide (“AZO”). The cell may be constructed by sequential deposition of the thin film layers. In this example, CdS is used as the buffer layer and AZO is used as the top transparent conductive oxide front contact. Photo-conversion is accomplished with the absorption of electromagnetic radiation in the top-most regions of the chalcogenide material and the efficient production of electron-hole pairs and their collection by the p-n junction formed between the chalcogenide and the buffer layer materials (e.g. cadmium sulfide, zinc sulfide, indium sulfide, indium selenide, cadmium selenide, zinc selenide, zinc indium selenide, indium oxide and cadmium oxide).

In a photovoltaic article having a single photovoltaic cell, incident photons with energies below the band gap of the absorber layer cannot generate an electron-hole pair, and therefore either pass through the material unabsorbed or are scattered within the material to generate heat. Photons with energies above the band gap of the absorber material do excite electron-hole pairs, which become useful electrical output. However, the excess photon energy also results in scattering within the material, thereby generating heat, which is then lost. These losses limit the useful output of PV cells. To improve photovoltaic conversion efficiencies, multi-junction solar cells have been constructed. Such cells are typically composed of several layers of material that have different band gaps. The top layer has the largest band gap while the bottom layer has the smallest band gap. This design allows less energetic photons to pass through the upper layer(s) and be absorbed by a lower layer, resulting in an increase in the overall efficiency of the solar cell.

The top cell is generally comprised of a wider band gap absorber material tuned to higher energy photons than the series cell beneath it. The lower cell has a smaller band gap energy and is tuned for the lower energy component of the incident light. Examples of conventional multi-junction PV cells include InGaP/GaAs-based multi-junction solar cells and multi-junction solar cells with CIS or CIGS as the bottom absorber and amorphous silicon as the top absorber. In both cases, the materials used in the top cell are robust with regard to exposure to environmental conditions—e.g. exposure to water.

Applicants have discovered that when CIGSS-based top cells are used certain materials frequently used as additional active layers, such as AZO and CdS, are prone to degradation in moisture-rich and/or oxygen-rich environments. This environmental sensitivity puts an added burden on the choice of encapsulation or packaging scheme for the solar cell, in that a transparent and completely air- and water-tight front side to the cell must be provided with the traditional configuration of the CIS- and CIGS-based PV cells. Only glass has been identified as meeting the necessary barrier properties to protect such sensitive materials. Unfortunately, if glass is used, the cell may not have the flexibility desired or theoretically attainable in a CIGSS based PV cell.

The embodiments described below reduce the need for a passive barrier layer or reduce the stringency of the requirements for such a passive barrier layer. The embodiments described below also enable the PV cell to maintain flexibility by avoiding use of glass as a barrier layer. These benefits are obtained while maintaining adequate lifetimes of the PV cells.

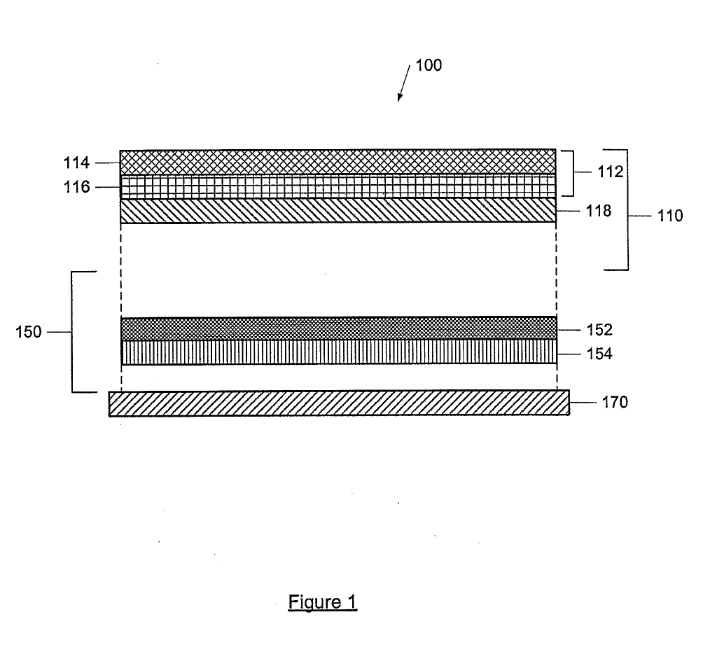

Typically each of the plurality of layers will include absorber, buffer and transparent conductive oxide layers. There may also be an optional window layer between the buffer layer and the transparent conductive oxide layer. This window layer protects the device from shunts and can protect the buffer layer during deposition of the transparent conductive oxide. The window layer is typically a resistive transparent oxide such as an oxide of Zn, In, Cd, Sn, but is preferably intrinsic or undoped ZnO. Referring to FIG. 1, in one aspect of the present disclosure, a multi-junction photovoltaic device 100 includes (a) an upper photovoltaic cell portion 110 that has a first plurality of active layers of films, at least a subset (in this example layers 116 and 118) of which form an upper photovoltaic sub-cell and (b) a lower photovoltaic cell portion 150 disposed below the upper photovoltaic cell portion that has a second plurality of layers of films, at least a subset (in this example layers 152 and 154) of which form a lower photovoltaic sub-cell. The lower cell portion 150 is disposed on a substrate 170, which can be either rigid or flexible. The multi-junction PV cell 100 can therefore be either rigid or flexible.

The photon absorption property of the upper cell portion 110 is characterized by the band gap of the absorber layer 116 of the upper sub-cell. Thus, the upper sub-cell is adapted to absorb photons having energy levels equal to greater than the band gap of the absorber layer 116 and to transmit the photons with lower energy levels. The lower cell portion 150, which is characterized by the smaller band gap of its absorber layer (in one example layer 154), then receives the photons passing through the upper photovoltaic cell portion 110.

The first plurality of active layers, of the upper cell portion, include at least two layers of films 112 and 118 having different degrees of robustness from each other against environmental conditions, such as exposure to water or oxygen. The two active layers 112 and 118 are disposed such that the layer 118 having the lower degree of robustness is located below the other layer 112 having the higher degree of robustness. In this illustrative embodiment, the layer 112 having the higher degree of robustness is the uppermost layer of the multi-junction photovoltaic device 100 and thus be exposed to the environment in operation. With this arrangement, the upper layer 112 serves both as an active layer in the upper cell portion and as a protective layer for the less robust layer 118 against the environmental conditions, thereby reducing or eliminating the need or requirements for an extra, passive protective layer, which may increase the complexity of the article or may reduce the efficiency of the photovoltaic device. However, other layers, such as a glass, semiconductor, ceramic, polymeric or other encapsulating layer can be disposed on top of the upper layer 112 as specific applications may require.

In another aspect of the present disclosure, at least one of the first plurality of active layers of films can comprise a layer of IB-IIIA-chalcogenide, such as IB-IIIA-selenides, IB-IIIA-sulfides, or IB-IIIA-selenide sulfides. More specific examples include copper indium selenides, copper indium gallium selenides, copper gallium selenides, copper indium sulfides, copper indium gallium sulfides, copper gallium selenides, copper indium sulfide selenides, copper gallium sulfide selenides, and copper indium gallium sulfide selenides (all of which are referred to herein as CIGSS). These can also be represented by the formula CuIn(1−x)GaxSe(2−y)Sy where x is 0 to 1 and y is 0 to 2. The copper indium selenides and copper indium gallium selenides are preferred. For example, layer 116 can be an absorber layer comprising a IB-IIIA-chalcogenide such as copper indium selenide, copper indium gallium selenide or copper gallium selenide in this illustrative embodiment.

In another aspect, the layer 112 having the higher degree of robustness of the two layers can comprise a first transparent conducting oxide layer. In this illustrative embedment, top layer 114 is a conductive transparent oxide (“TCO”) layer comprising an indium-doped tin oxide (“ITO”) but can be made of other suitable TCO such as tin oxide, indium oxide, tin-doped indium oxide fluorine-doped tin oxide, titanium oxide, zirconium oxide or a combination thereof.

In another aspect, the layer having the lower degree of robustness can comprise a layer of a sulfide or an oxide of a metal selected from a group consisting of cadmium, zinc or combinations thereof. For example, the layer having the lower degree of robustness can comprise a layer comprising cadmium and sulfur and an adjacent layer comprising zinc and oxygen. As a more specific example, buffer layer 118 can comprise CdS, forming a heterojunction PV cell with the chalcogenide absorber layer 116 but can also be made of other materials suitable for buffer layers. As a further example, there can be a transition layer (not shown in FIG. 1) comprising an oxide layer, such as one of oxides of Zn, In, Sn, Ti, and the like, disposed below the buffer layer 118.

In the illustrative embodiment shown in FIG. 1, the layer 112 having the higher degree of robustness comprises two layers of films 114 and 116, both having higher degrees of robustness than the layer 118 having the lower degree of robustness. In a further embodiment, the upper layer 114 has a higher degree of robustness than layer 116. Thus, in that example, the three layers 114, 116 and 118 are disposed deeper into the multi-junction PV cell 100 in the order of progressively lower degrees of robustness, and each or the interior layers 116 and 118 is protected by at least one layer that is more robust than itself.

In another aspect of the present disclosure, at least one of the second plurality of layers of films, in the lower cell portion 150, comprises a layer of IB-IIIA-chalcogenide, such as IB-IIIA-selenide, such as copper indium selenide, copper indium gallium selenide or copper gallium selenide. For example, layer 154 can be an absorber layer comprising a IB-IIIA-chalcogenide such as CIS, CIGS and CGS in this illustrative embodiment. Further, layer 152 can be a buffer layer comprising, for example, CdS, thereby forming a heterojunction PV cell.

The substrate 170 can be made of any material suitable for constructing PV cell substrates. Examples include glass, polymers, ceramic materials and metals. In certain embodiments, the substrate layer 170 is made of a conductive material, such as a molybdenum foil. In such cases, the substrate layer 170 can function both as a support for the PV cell and an electrical contact layer, and a separate contact layer for the bottom cell portion (such as the lower cell portion 150 in a two junction PV cell can be omitted.

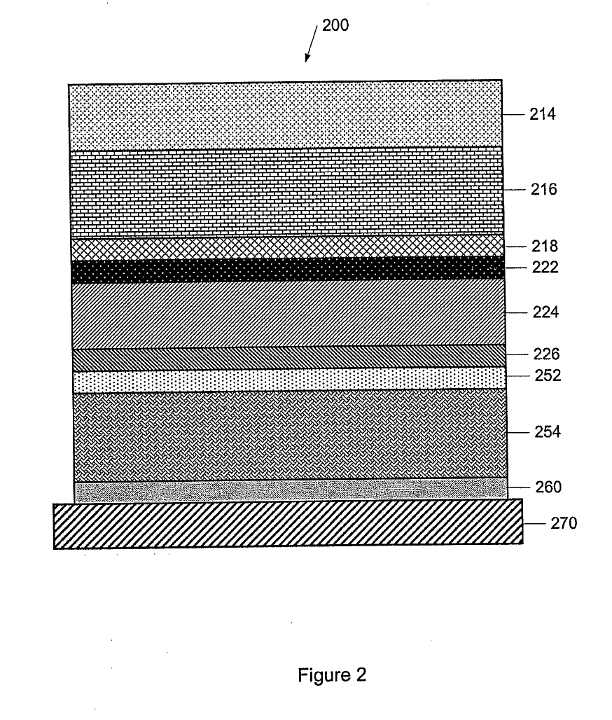

FIG. 2 illustrates another embodiment according to the present disclosure. In this embodiment, the multi-junction PV cell comprises the following layers in sequence, from bottom up:
a substrate 270 (a rigid or flexible substrate, for example glass, polymer, ceramic, semiconducting, or metal based);
a metallic and electrical back contact 260, for example, molybdenum (which can also be the same as 270);
a p-type absorber material 254, for example, a chalcogenide such as copper indium selenide, copper indium gallium selenide or copper gallium selenide (however, other p-type absorbers besides chalcogenides may be used instead);
an n-type junction emitter, or buffer, layer 252, such as cadmium sulfide, zinc sulfide, indium sulfide, indium selenide, cadmium selenide, zinc selenide, zinc indium selenide, indium oxide and cadmium oxide;
an insulating portion of the “window layer” 226, for example, an oxide of Zn, In, Cd, Sn;
a transparent conductive material 224 such as fluorine-doped tin oxide, tin oxide, indium oxide, ITO, AZO and zinc oxide;
an insulating portion of the “window layer” 222, for example, an oxide of Zn, In, Cd, Sn, etc;
an n-type emitter, or buffer, material 218 such as cadmium sulfide, zinc sulfide, indium sulfide, indium selenide, cadmium selenide, zinc selenide, zinc indium selenide, indium oxide and cadmium oxide;
a p-type wide band gap (i.e., with a higher energy band gap than layer 254) absorber chalcogenide material 216 such as copper indium selenide, copper indium gallium selenide and copper gallium selenide;
a front side transparent electrical contact 214, for example, a TCO such as indium-tin oxide.

In the illustrative embodiments described above, the buffer layers (118 and 152 in FIG. 1 and 218 and 252 in FIG. 2) are disposed between the absorber layers (116 and 154 in FIG. 1 and 216 and 254 in FIG. 2, respectively). Thus, the upper and lower photovoltaic sub-cells have opposite polarities from each other, i.e., the n-type side of the pn junction (such as CdS layers) of the two sub-cells are disposed between the p-type side of the pn junction (such as IB-IIIA-chalcogenide layers) of the sub-cells, or vice versa. The upper and lower sub-cells are therefore connected in parallel and thus capable of supplying a larger current than single junction cells or conventional multi-junction PV cells. In other embodiments, the relative spatial locations of the p-type and n-type layers can be altered as appropriate.

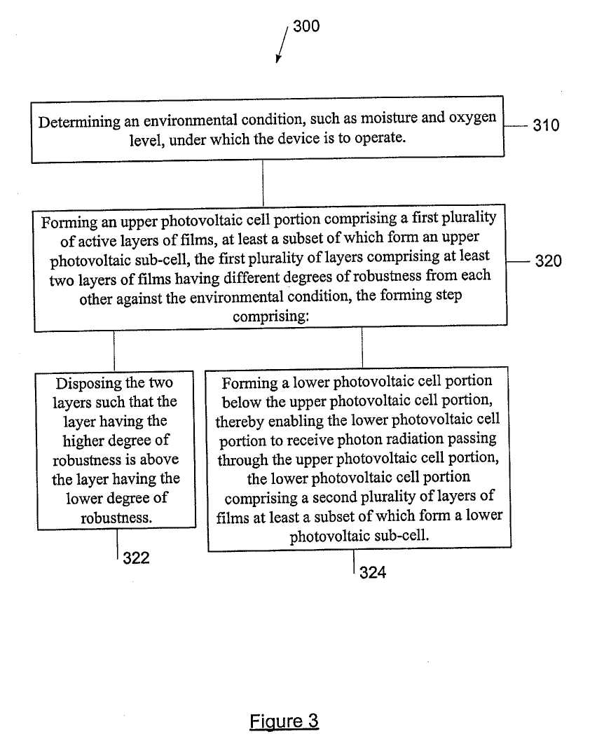

In a further aspect of the disclosure, referring to FIG. 3, a method of making a multi-junction photovoltaic device in one embodiment includes (a) determining an environmental condition 310, such as moisture and oxygen level, under which the device is to operate and (b) forming an upper photovoltaic cell portion comprising a first plurality of active layers of films, at least a subset of which form an upper photovoltaic sub-cell, the first plurality of layers comprising at least two layers of films having different degrees of robustness from each other against the environmental condition 320. The forming step 320 comprising: (i) disposing the two layers such that the layer having the higher degree of robustness is above the layer having the lower degree of robustness, and (ii) forming a lower photovoltaic cell portion below the upper photovoltaic cell portion, thereby enabling the lower photovoltaic cell portion to receive photon radiation passing through the upper photovoltaic cell portion, the lower photovoltaic cell portion comprising a second plurality of layers of films at least a subset of which form a lower photovoltaic sub-cell. The materials used for the various layers can be those described above for the illustrative multi-junction PV cells but are not limited to those materials.

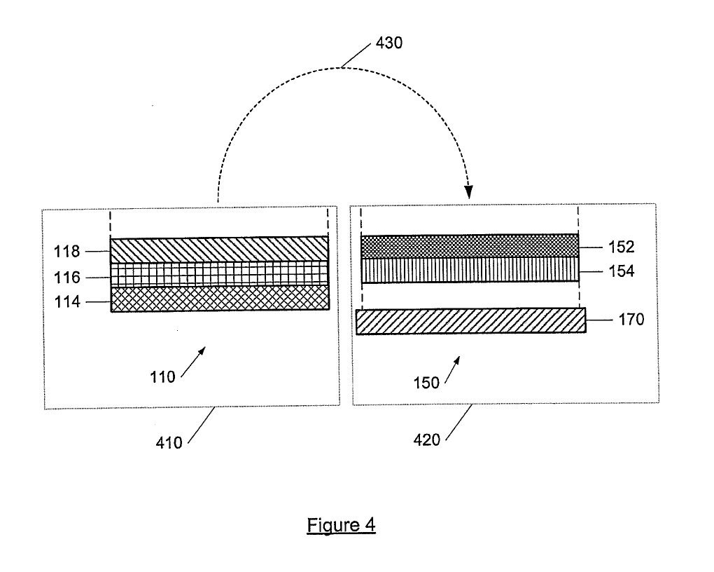

In one embodiment, as illustrated in FIG. 4, the multi-junction photovoltaic device (e.g., 100) can be made by joining the upper and lower cell portions 110 and 150 after both portions have been formed, making a mechanically stacked multi-junction PV cell. In this embodiment, in one part (410) of the process to make the upper PV cell portion 110, a sheet 114 that will become the uppermost layer in the PV cell 100 is used as a substrate (also referred to as a “superstate”) upon which other film layers, including the absorber layer 116 and buffer layer 118, of the upper cell portion 110 are deposited. Similarly, in another part (420) of the process to make the lower PV cell portion 150, a substrate 170 is provided upon which other film layers, including the back contact layer (not shown in FIG. 4), absorber layer 154 and buffer layer 152, of the upper cell portion 150 are deposited. All methods suitable for thin film deposition of the chosen materials can be used, including chemical bath, physical vapor deposition techniques, electron beam evaporation, molecular beam epitaxy, sputtering (reactive, RF, DC, pulsed DC), chemical vapor deposition (low pressure, plasma enhanced), mechanical application (pastes, spray deposition, nanoparticle deposition, wire bonding, ink), sintering, reactive or other techniques as used in printed circuit board manufacturing, semiconductor manufacturing, etc. Additional layers, such as the window layers (for example, the iZnO layers 222 and 226, as well as the transparent conductive materials 224 and 214 in FIG. 2) can be deposited on either the upper cell portion 110 or the lower cell portion 150. Alternatively, some of the additional layers can be deposited on the upper cell portion 110 while the others layers can be deposited on the lower cell portion 150.

After the two halves of the PV cell 100 are completed, they can be joined (430) to form a multi-junction PV cell. Various methods can be used to join the two halves. A preferred method is lamination via mechanical pressing.

In another embodiment, a multi-junction photovoltaic device can also be made by sequentially forming each layer on top of those already formed, thereby forming a monolithically stacked PV cell. In such a process, naturally, the upper PV cell portions and lower PV cell portions are formed in order, or reverse order, where as in the process illustrated in FIG. 3, steps 410 and 420 need not be carried out in any particular order.

With the embodiments described above, the most environmentally-sensitive materials in multi-junction PV cells are positioned on the inside of the device and the environmentally-stable materials are positioned on the outside of the device. This device architecture may reduce the need to use additional encapsulation layers. This provides, in a cost-effective way, for a longer life of the complete PV cells in conditions (such as outdoors) where the cells are exposed to environmental conditions.

Those skilled in the art will recognize that the methods and devices of the present disclosure may be implemented in many manners and as such are not to be limited by the foregoing embodiments and examples. Moreover, the scope of the present disclosure covers conventionally known manners for carrying out the described features and functions, as well as those variations and modifications that may be made to the materials and shapes of the components described herein as would be understood by those skilled in the art now and hereafter.

While various embodiments have been described for purposes of this disclosure, such embodiments should not be deemed to limit the teaching of this disclosure to those embodiments. Various changes and modifications may be made to the elements and operations described above to obtain a result that remains within the scope of the systems and processes described in this disclosure. Numerous other changes may be made that will readily suggest themselves to those skilled in the art and which are encompassed in the spirit of the invention disclosed and as defined in the appended claims.

What is claimed is:

1. A multi-junction photovoltaic device, comprising:
an upper photovoltaic cell portion comprising a first plurality of active layers of films, at least a subset of which forming an upper photovoltaic sub-cell, the upper cell portion being adapted to absorb a first spectral portion of a photon radiation and to transmit a second spectral portion of the photon radiation,
the first plurality of active layers comprising at least two layers of films having different degrees of robustness from each other against an environmental condition and disposed such that the layer having the lower degree of robustness is located below the other layer having the higher degree of robustness; and
a lower photovoltaic cell portion disposed below the upper photovoltaic cell portion and adapted to receive the photon radiation passing through the upper photovoltaic cell portion, and comprising a second plurality of layers of films at least a subset of which forming a lower photovoltaic sub-cell.

2. The device of claim 1, wherein at least one of the first plurality of active layers of films comprises a layer of IB-IIIA-chalcogenide,

3. The device of claim 2, wherein the two layers of films have different degrees of robustness from each other against oxygen or water, or both.

4. The device of claim 2, wherein the layer having the higher degree of robustness comprises two layers of films, both having higher degrees of robustness than the layer having the lower degree of robustness.

5. The device of claim 4, wherein the layer having the highest degree of robustness of the three layers comprises a first transparent conducting oxide layer.

6. The device of claim 2, wherein the layer of IB-IIIA-chalcogenide comprises a IB-IIIA-selenide.

7. The device of claim 2, wherein the layer having the lower degree of robustness comprises a layer of a sulfide or an oxide of a metal selected from a group consisting of cadmium, zinc or combinations thereof.

8. The device of claim 7, wherein the layer having the lower degree of robustness comprises a layer comprising cadmium and sulfur and an adjacent layer comprising zinc and oxygen.

9. The device of claim 1, wherein the layer having the higher degree of robustness is exposed to the environment.

10. The device of claim 4, wherein the first transparent conducting oxide comprises tin oxide, indium oxide, tin-doped indium oxide, fluorine-doped tin oxide, titanium oxide, zirconium oxide or a combination thereof.

11. The device of claim 2, wherein at least one of the second plurality of layers of films comprises a layer of IB-IIIA-chalcogenide.

12. The device of claim 1, wherein the upper and lower photovoltaic sub-cells are connected to each other by a transition layer comprising a second transparent conducting oxide.

13. The device of claim 1, wherein the upper and lower photovoltaic sub-cells have opposite polarities from each other.

14. A multi-junction photovoltaic device, comprising:
an upper photovoltaic cell portion comprising a first plurality of active layers of films, at least a subset of which forming an upper heterojunction photovoltaic sub-cell comprising a first absorber layer and a first buffer layer,
the upper cell portion being adapted to absorb a first spectral portion of a photon radiation and to transmit a second spectral portion of the photon radiation; and
a lower photovoltaic cell portion disposed below the upper photovoltaic cell portion and adapted to receive the photon radiation passing through the upper photovoltaic cell portion and comprising a second plurality of active layers of films, at least a subset of which forming a lower heterojunction photovoltaic sub-cell comprising a second absorber layer and a second buffer layer,
the buffer layers being disposed between the absorber layers.

15. The device of claim 14, wherein each of the absorber layers comprises a IB-IIIA-chalcogenide, and each of the buffer layers comprises a layer of a sulfide or oxide of a metal selected from a group consisting of cadmium, zinc and combinations thereof.

16. The device of claim 1, the device being flexible.

17. A method of making a multi-junction photovoltaic device for operation under an environmental condition, the method comprising:
forming an upper photovoltaic cell portion comprising a first plurality of active layers of films, at least a subset of which forming an upper photovoltaic sub-cell, the first plurality of layers comprising at least two layers of films having different degrees of robustness from each other against the environmental condition, the forming step comprising:
disposing the two layers such that the layer having the higher degree of robustness is above the layer having the lower degree of robustness; and
forming a lower photovoltaic cell portion below the upper photovoltaic cell portion, thereby enabling the lower photovoltaic cell portion to receive photon radiation passing through the upper photovoltaic cell portion, the lower photovoltaic cell portion comprising a second plurality of layers of films at least a subset of which forming a lower photovoltaic sub-cell.

18. The method of claim 17, where the step of forming the lower photovoltaic cell portion below the upper photovoltaic cell portion comprises joining the two portions after forming both portions.

19. The method of claim 17, further comprising forming a transition layer comprising a transparent conductive oxide layer between the upper and lower photovoltaic sub-cells.

20. The method of claim 17, wherein the step of forming the upper photovoltaic cell portion comprises depositing a transparent conductive oxide film, a IB-IIIA-chalcogenide film and a CdS film either in order, or in reverse order, so that the transparent conductive oxide film is the uppermost of the three layers in the multi-junction photovoltaic device.
